(19) United States
(12) Patent Application Publication
(10) Pub. No.: US 2024/0201586 A1
(43) Pub. Date: Jun. 20, 2024

(54) PRECURSORS AND METHODS FOR PRODUCING TIN-BASED PHOTORESIST

(71) Applicant: Intel Corporation, Santa Clara, CA (US)

(72) Inventors: James Blackwell, Portland, OR (US); Charles Cameron Mokhtarzadeh, Portland, OR (US); Lauren Elizabeth Doyle; Eric Mattson, Portland, OR (US); Patrick Theofanis, Portland, OR (US); John J. Plombon, Portland, OR (US); Michael Robinson, Beaverton, OR (US); Marie Krysak, Portland, OR (US); Paul Meza-Morales, Hillsboro, OR (US); Scott Semproni, Portland, OR (US); Scott B. Clendenning, Portland, OR (US)

(73) Assignee: Intel Corporation, Santa Clara, CA (US)

(21) Appl. No.: 18/068,732

(22) Filed: Dec. 20, 2022

(51) Int. Cl. G03F 7/004; G03F 7/038; G03F 7/16; G03F 7/20; G03F 7/38

(52) U.S. Cl. CPC G03F 7/0042; G03F 7/038; G03F 7/167; G03F 7/2004; G03F 7/38

(57) ABSTRACT

Precursors and methods related to a tin-based photoresist are disclosed herein. In some embodiments, a method for forming a tin-based photoresist may include exposing a tin-containing precursor and a co-reagent to a substrate to form a photoresist having tin clusters; selectively exposing the photoresist to extreme ultraviolet radiation (EUV); and exposing the photoresist to heat to form, in the region, crosslinking between the tin clusters. In some embodiments, the precursor has a formula R¹R²Sn(N(CH₃)₂)₂, and R¹ and R² are selected from the group consisting of neo-silyl, neo-pentyl, phenyl, benzyl, methyl-bis(trimethylsilyl), methyl, ethyl, isopropyl, tert-butyl, n-butyl, N,N-dimethylpropylamine, and N, N-dimethlybutylamine. In other embodiments, the precursor includes a chelating alkyl-amine or alkyl-amide ligand featuring a 5 membered or 6 membered tin-based heterocycle bound κ²-C,N with an alkyl group on the ligand backbone, wherein the alkyl group includes methyl, ethyl, vinyl, hydrogen, or tert-butyl.

### TECHNICAL FIELD

The present disclosure relates to manufacturing integrated circuits (ICs). More specifically, it relates to techniques, methods, and materials directed to metal oxide photoresist films for patterning.

### BACKGROUND

Electronic circuits when commonly fabricated on a wafer of semiconductor material, such as silicon, using lithography. Such electronic circuits are called ICs. ICs are typically fabricated by sequentially depositing and patterning layers of dielectric, conductive, and other semiconductor materials over a substrate to form an electrically connected network of electronic components and interconnect elements (e.g., capacitors, transistors, resistors, conductive traces, pads, and vias) integrated in a monolithic structure. A wafer with such ICs is typically cut into numerous individual dies. The dies may be packaged into an IC package containing one or more dies along with other electronic components. The IC package may be integrated onto an electronic system, such as a consumer electronic system.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1E illustrate cross-sectional views of an example fabrication process for forming, patterning, and developing a tin-based photoresist on a substrate according to some embodiments of the present disclosure.

FIG. 2 illustrates an example tin-containing precursor according to some embodiments of the present disclosure.

FIG. 3 illustrates other example tin-containing precursors according to some embodiments of the present disclosure.

FIG. 4 illustrates a reaction of an example tin-containing precursor and a co-reagent to form a tin-based photoresist according to some embodiments of the present disclosure.

FIGS. 5A and 5B illustrates a reaction of other tin-containing precursors and a co-reagent to form another tin-based photoresist according to some embodiments of the present disclosure.

FIG. 6 illustrates example reactions of a tin-based photoresist according to some embodiments of the present disclosure.

FIG. 7 is a schematic flow diagram listing example operations that may be associated with forming a tin-based photoresist according to some embodiments of the present disclosure.

### DETAILED DESCRIPTION

For purposes of illustrating IC packages manufactured using photolithography described herein, it is important to understand phenomena that may come into play during developing a metal oxide photoresist. The following foundational information may be viewed as a basis from which the present disclosure may be properly explained. Such information is offered for purposes of explanation only and, accordingly, should not be construed in any way to limit the broad scope of the present disclosure and its potential applications.

Photolithography is commonly used to pattern thin films during semiconductor processing, where photons are emitted from a light source onto a photosensitive photoresist to initiate a chemical reaction in the photoresist. When exposed to light, a photoresist may be further polymerized or cross linked to form a hardened coating which is resistant to etching solutions (e.g., negative-type photoresist) or may become more easily decomposable or dissolvable (e.g., positive-type photoresist). Thereafter, the photoresist is developed and exposed or unexposed portions of the photoresist are removed to form a pattern or a mask. Current photolithography processes use ultraviolet (UV) light with a wavelength between 10 nanometers and 400 nanometers or extreme ultraviolet radiation (EUV) with a wavelength between 10 nanometers and 15 nanometers (e.g., 13.5 nanometers+/−2%), which may be used for providing improved pattern resolution in advanced integrated circuits where reduction in feature sizes is required. Metal oxide photoresists, particularly photoresists containing tin (Sn) metal, may be especially suitable for EUV photopatterning. A photoresist can be crucial to maintaining circuit element tolerances. A photoresist may be susceptible to degradation due to exposure from air or water, for example, during manufacturing processes delays. In some instances, a degraded photoresist may become more easily removed, which may cause the photoresist to dissolve and/or lift away from the substrate and further expose the underlying material (e.g., a metal, a dielectric, or a hard mask) resulting in decreased resolution and additional underlying metal to be etched away. In some instances, a degraded photoresist may become more difficult to remove, which may result in an open defect, may require extended EUV exposure, and/or a longer time for developing. A degraded photoresist may result in inaccurate patterning and other defects, which decreases manufacturing yields and increases costs. Ways to mitigate the degradation of a photoresist may be desired.

Accordingly, precursors and methods related to a tin-based photoresist are disclosed herein. In some embodiments, a method for forming a tin-based photoresist may include exposing a tin-containing precursor and a co-reagent to a substrate to form a photoresist having tin clusters; selectively exposing the photoresist to EUV to form a region in the photoresist that is activated for crosslinking between the tin clusters; and exposing the photoresist to heat to form, in the region, long range crosslinking between the tin clusters within the photoresist. In some embodiments, the precursor has a formula R¹R²Sn(N(CH₃)₂)₂, and R¹ and R² are selected from the group consisting of neo-silyl, neo-pentyl, phenyl, benzyl, methyl-bis(trimethylsilyl), methyl, ethyl, isopropyl, tert-butyl, n-butyl, N,N-dimethylpropylamine, and N, N-dimethlybutylamine. In other embodiments, the precursor includes a chelating alkyl-amine/alkyl-amide ligand featuring a 5 membered or 6 membered tin-based heterocycle bound K(kappa)₂-C,N with an alkyl group on the ligand backbone. In some embodiments, the co-reagent includes water, carboxylic acid, phosphonic acid, sulphonic acid, or hydrogen peroxide.

Each of the methods and materials of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The term “coupled” means either a direct connection (which may be one or more of a mechanical, electrical, and/or thermal connection) between the things that are connected, or an indirect connection through one or more intermediary objects between the things that are connected.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The term “dispose” as used herein refers to position, location, placement, and/or arrangement rather than to any particular method of formation.

The term “between,” when used with reference to measurement ranges, is inclusive of the ends of the measurement ranges.

The terms “substantially,” “close,” “approximately,” “near,” and “about,” generally refer to being within +/−20% of a target value (e.g., within +/−5% or 10% of a target value) based on the context of a particular value as described herein or as known in the art.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

In the drawings, a particular number and arrangement of components are presented for illustrative purposes and any desired number or arrangement of such components may be present in various embodiments.

For convenience, if a collection of reference numerals designated with different numerals and/or letters are present (e.g., 101-1, 101-2A, 101-2B, etc.), such a collection may be referred to herein without the numerals and/or letters (e.g., as “101-1, 101-2” or as “101”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

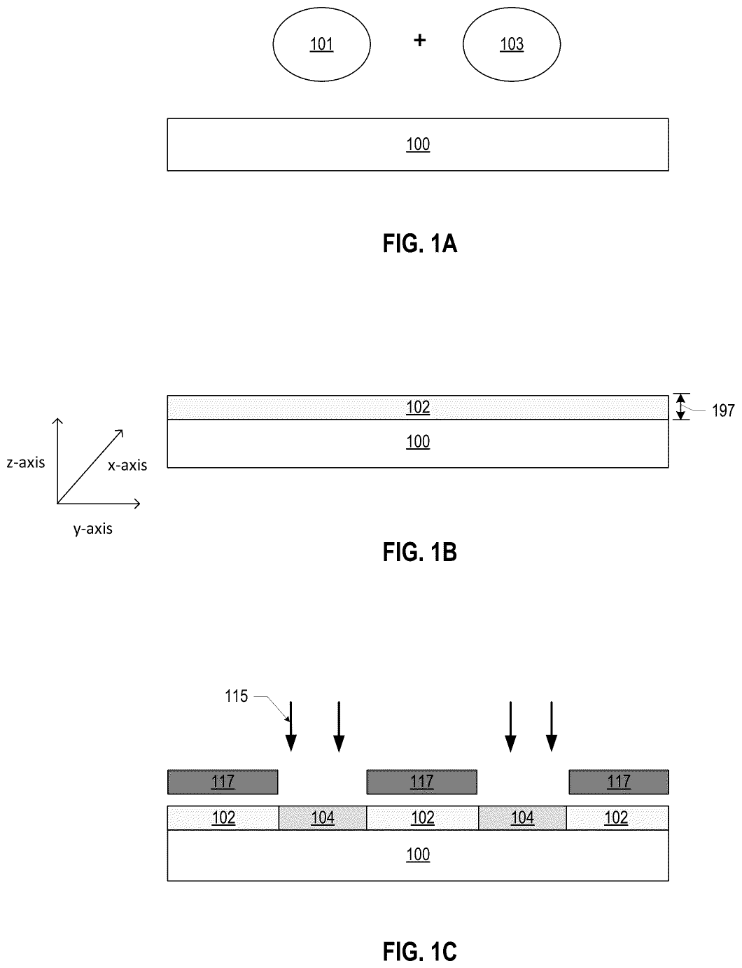

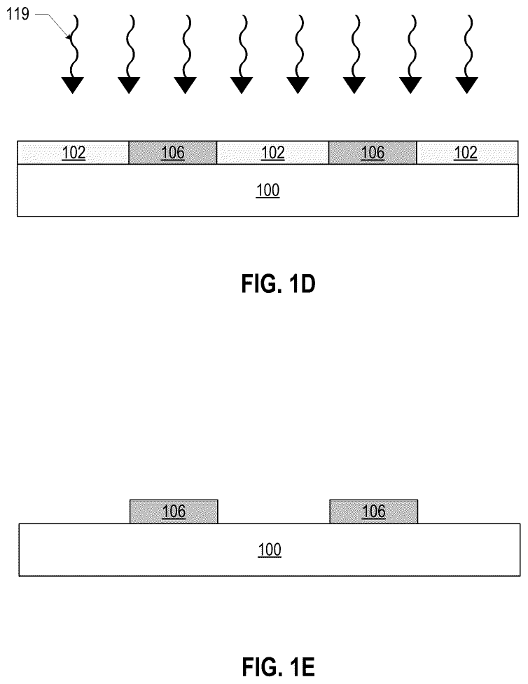

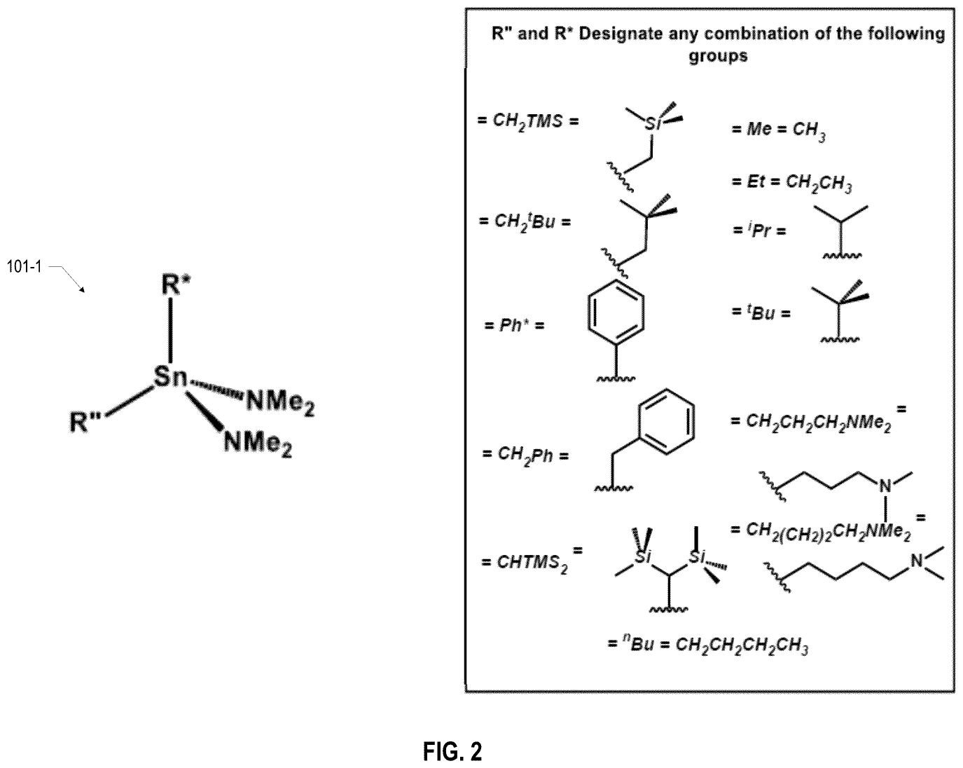

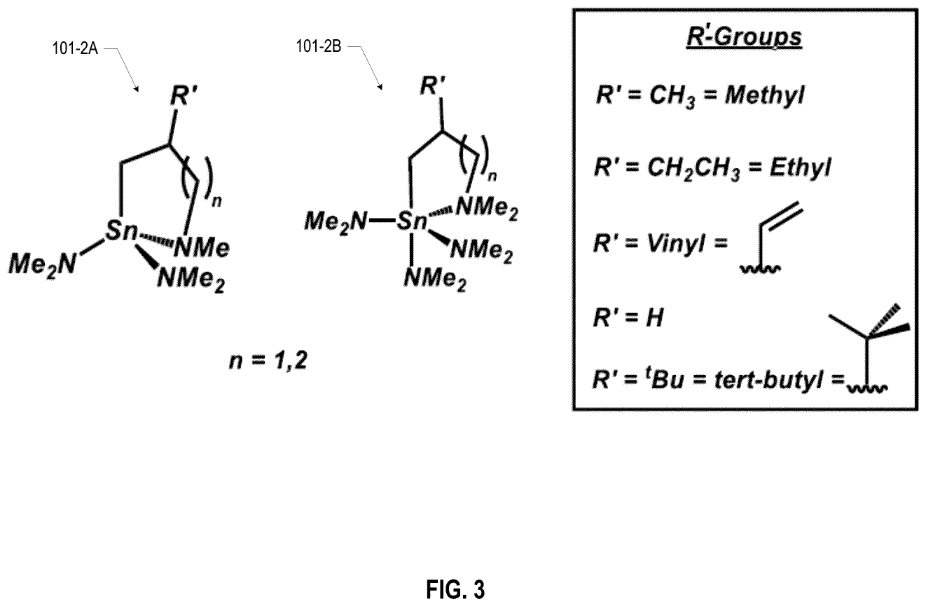

FIGS. 1A-1E illustrate cross-sectional views of an example fabrication process for forming, patterning, and developing a tin-based photoresist on a substrate according to some embodiments of the present disclosure. FIG. 1A illustrates a tin-containing precursor 101 and a co-reagent 103 being exposed to a substrate 100. A substrate 100 may include a semiconductor material, such as silicon, and may include a wafer or a panel. In some embodiments, a substrate 100 may include multiple layers of dielectric material with conductive pathways therein. A tin-containing precursor 101 may have a formula R¹R²Sn(N(CH₃)₂)₂ (e.g., as described below with reference to a precursor 101-1 in FIG. 2) or may include a chelating alkyl-amide or alkyl-amine ligand featuring a 5 or 6 membered tin-based heterocycle bound κ²-C,N with an alkyl group on the ligand backbone (e.g., as described below with reference to a precursor 101-2 in FIG. 3). A co-reagent 103 may include water, carboxylic acid, phosphonic acid, sulphonic acid, or hydrogen peroxide.

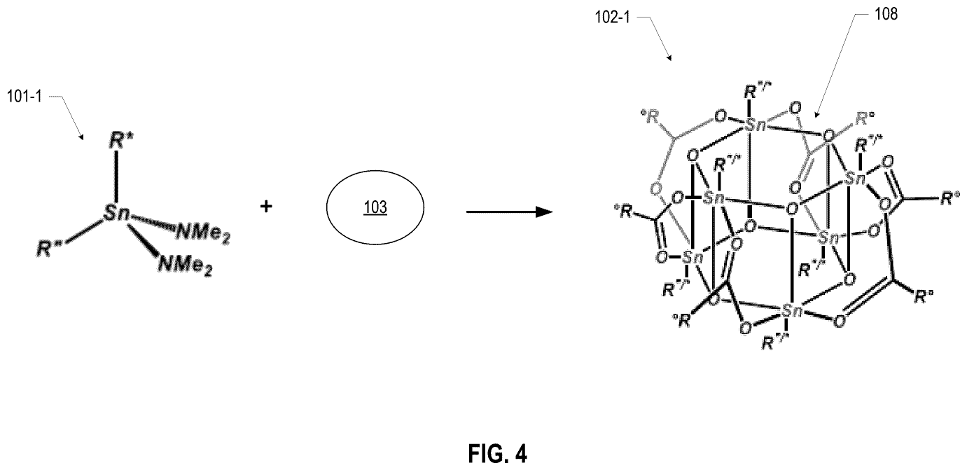

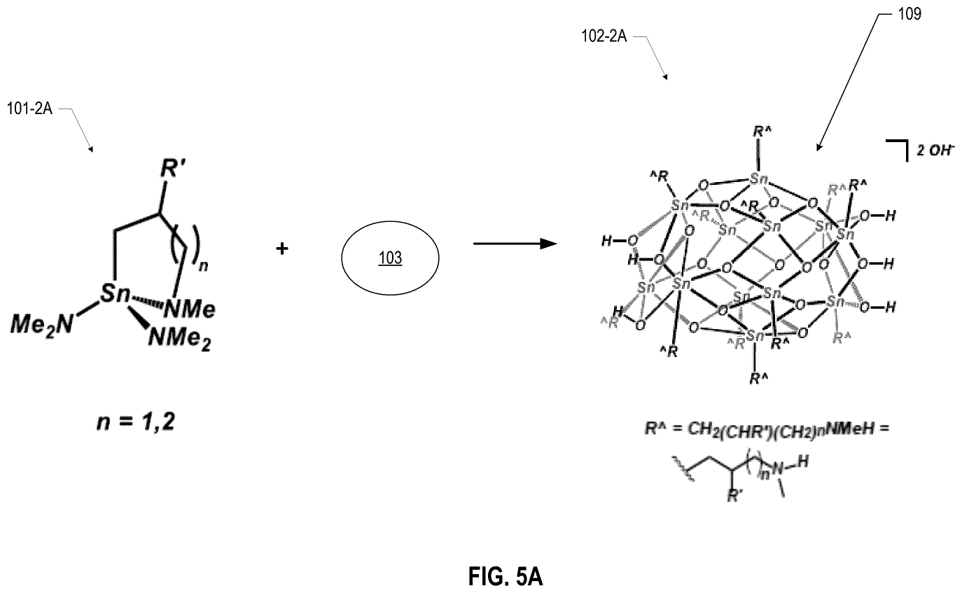

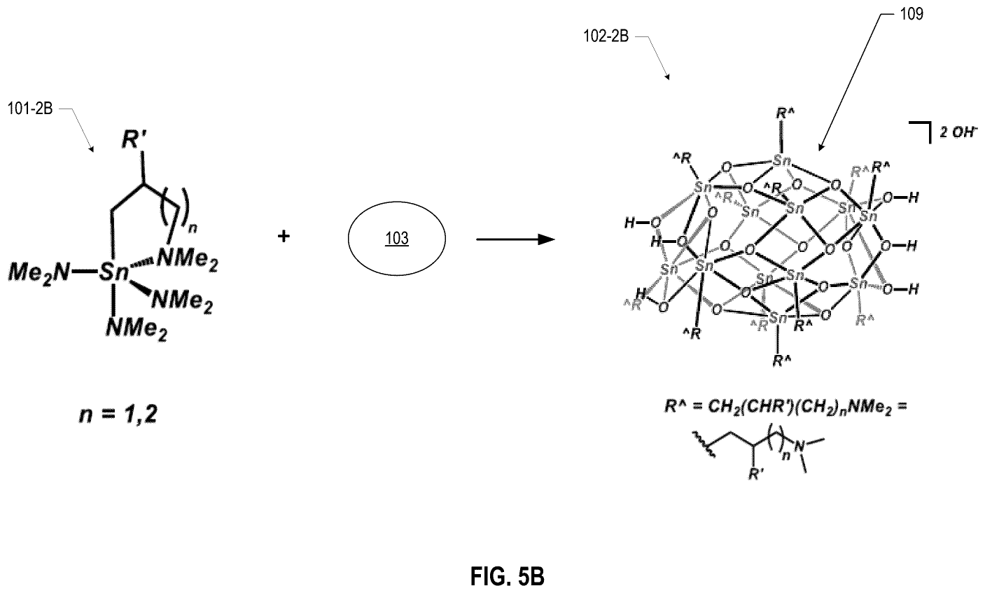

FIG. 1B illustrates an assembly subsequent to forming a tin-based photoresist 102 on the substrate 100. The tin-based photoresist 102 may include tin clusters (e.g., bonded structures) having a drum-shape 108 or a football-shape 109, as described below with reference to FIGS. 4 and 5, respectively. The tin-based photoresist 102 may have a thickness 197 (e.g., z-height) between 10 nanometers and 100 nanometers. The tin-based photoresist 102 may be formed using any suitable deposition process, such as chemical vapor deposition (CVD) or atomic layer deposition (ALD). For example, the tin-based photoresist 102 may be formed by exposing the substrate 100 to the tin-containing precursor 101 and the co-reagent 103 in a process chamber, which may be performed stepwise or simultaneously. In some embodiments, the deposition process may include two or more exposing steps. For example, the ALD process may be performed by first exposing the substrate 100 to the vaporized tin-containing precursor 101 and, thereafter, exposing the substrate 100 to the vaporized co-reagent 103 to form the tin-based photoresist 102. The exposing steps may be repeated one or more times to increase a thickness of the tin-based photoresist 102 on the substrate 100. In certain embodiments, the exposing steps may be separated temporally or spatially by changing the gas composition in a process chamber or by utilizing multiple spatially segregated sections within the process chamber and transporting the substrate from one section to another. The vapor deposition process may further include evacuating, purging, or both evacuating and purging, the process chamber between the exposing steps. In another example, the CVD process may be performed by exposing the tin-containing precursor 101 and the co-reagent 103 the process chamber simultaneously to grow the tin-based photoresist 102. In some embodiments, the assembly of FIG. 1B may be baked (e.g., exposed to heat) to remove any excess solvents from a wet process and/or residual volatile byproducts from a dry process. The tin-based photoresist 102 may be detected and may be identified using any suitable imaging technique, including, for example, X-ray photoelectron spectroscopy (XPS), also known as electron spectroscopy for chemical analysis (ESCA), Fourier transform infrared (FTIR) spectroscopy, Time-of-Flight Secondary Ion Mass Spectrometry (TOF-SIMS), scanning electron microscopy (SEM) images, transmission electron microscope (TEM) images, ellipsometry, or non-contact profilometer, among others.

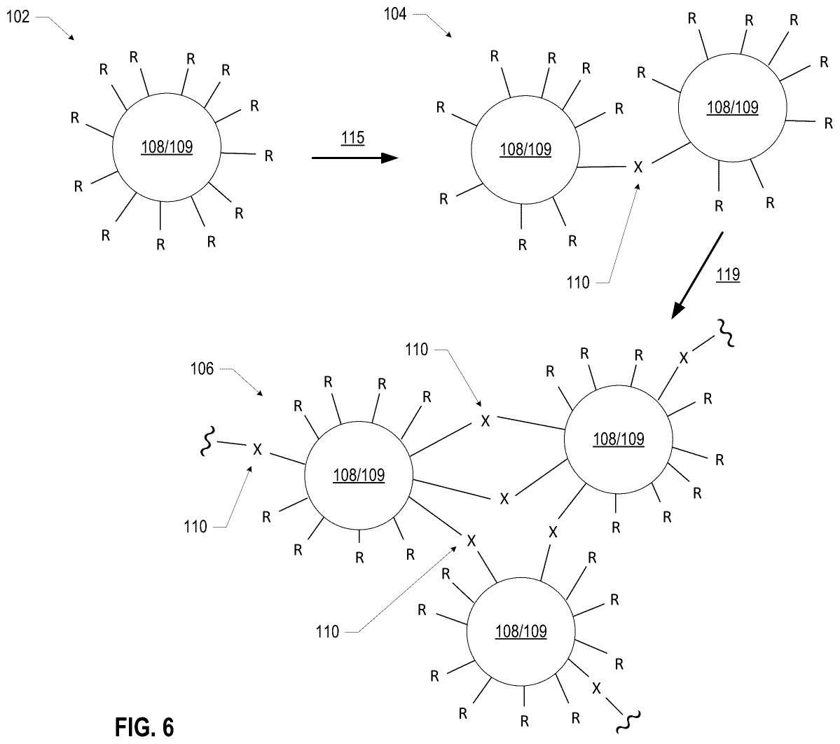

FIG. 1C illustrates an assembly subsequent to exposing the tin-based photoresist 102 to EUV 115 through a mask 117 and creating an activated region 104 in the tin-based photoresist 102 (e.g., crosslinking may be initiated between the tin clusters and/or the tin clusters may be activated for crosslinking when exposed to heat 119 (e.g., baking), as described below with reference to FIG. 1D). The mask 117 may selectively expose areas of the photoresist to EUV 115 to create the pattern (e.g., exposed regions and unexposed regions), which may be used as a guide for deposition of copper and other materials on the substrate. Exposure to EUV 115 may initiate or activate the crosslinking of the tin clusters in the tin-based photoresist 102, as described below with reference to FIG. 6.

FIG. 1D illustrates an assembly subsequent to baking (e.g., exposing to heat 119) the assembly of FIG. 1C to heat 119 and forming a crosslinked region 106 in the tin-based photoresist 102. For example, the assembly may be baked in a process chamber at a temperature between 70 degrees Celsius and 250 degrees Celsius to create regions 106 having large scale crosslinking of the tin clusters in the photoresist 102, as described below with reference to FIG. 6. The crosslinked region 106 may have material properties different than the tin-based photoresist 102 and the activated region 104. For example, the crosslinked region 106 may be less volatile, less reactive, and/or less soluble, and, as such, less susceptible to degradation.

FIG. 1E illustrates an assembly subsequent to developing and removing the unexposed regions of the tin-based photoresist 102 and the exposed regions (e.g., crosslinked regions 106) remain. The tin-based photoresist 102 may be developed by spraying or immersing the photoresist in a chemical solution (e.g., a developer solution), which dissolves the unexposed portions of the photoresist (e.g., in the case of a negative-type photoresist). When a negative-type photoresist is used, the mask will have a negative image of the pattern to be produced, such that the pattern created is an opposite image of the mask used. The unexposed regions of the tin-based photoresist 102 may be removed using any suitable process, such as a dry etch or a wet etch process. The assembly of FIG. 1E may undergo further manufacturing process to form one or more ICs.

FIG. 2 illustrates example tin-containing precursors according to some embodiments of the present disclosure. In some embodiments, a tin-containing precursor 101-1 may have a formula R¹R²Sn(N(CH₃)₂)₂, where R¹ is a first group (i.e., R* group) and R² is a second group (i.e., R″ group). The R* and R″ groups may include any of the alkyl, alkyl amine, aryl, and silyl groups shown in FIG. 2, including CH₂TMS (neo-silyl), CH₂^{t}Bu (neo-pentyl), Ph (phenyl), CH₂Ph (benzyl), CH(TMS)₂ (methyl-bis(trimethylsilyl)), CH₃ (methyl, also referred to herein as Me), CH₂CH₃ (ethyl, also referred to herein as Et), iPr (isopropyl), ^{t}Bu (tert-butyl), nBu (n-butyl), CH₂CH₂CH₂NMe₂ (N,N-dimethylpropylamine), and CH₂(CH₂)₂CH₂NMe₂ (N, N-dimethlybutylamine). For example, R* and R″ may include alkyl groups and the tin-containing precursor may include a dialkyl tin bisamide. In some embodiments, the R* and R″ groups are a same group. In some embodiments, the R* and R″ groups are different groups.

FIG. 3 illustrates other example tin-containing precursors according to some embodiments of the present disclosure. In some embodiments, a tin-containing precursor 101-2 may include a chelating alkyl-amide ligand featuring a 5 or 6 membered tin-based heterocycle bound κ²-C,N with an alkyl group on the ligand backbone (e.g., 101-2A) or may include a chelating alkyl-amine ligand featuring a 5 or 6 membered tin-based heterocycle bound κ²-C,N with an alkyl group on the ligand backbone (e.g., 101-2B). The tin-based heterocycle may be 5 membered or 6 membered depending on whether n equals 1 or 2, respectively. The tin-containing precursor 101-2 may include a single alkyl group (e.g., R′ group). The R′ group may include any of the groups shown in FIG. 3, including methyl, ethyl, vinyl, hydrogen, or tert-butyl.

FIG. 4 illustrates a reaction of an example tin-containing precursor 101-1 and a co-reagent 103 to form a tin-based photoresist 102-1 according to some embodiments of the present disclosure. A tin-containing precursor 101-1 may have a formula R¹R²Sn(N(CH₃)₂)₂, as described above with reference to FIG. 2. A co-reagent 103 may include water, carboxylic acid, phosphonic acid, sulphonic acid, or hydrogen peroxide, as described above with reference to FIG. 1. The tin-containing precursor 101-1 and the co-reagent 103 may be deposited on a substrate 100 using a deposition process (e.g., CVD) to form a first tin-based photoresist 102-1 having tin clusters with a drum-shaped structure 108. The first tin-based photoresist 102-1 may further include R⁰ groups. The R⁰ group may include an alkyl group or an aryl group in commercially available carboxylic acids, such as formic acid, acetic acid, or pivalic acid.

FIG. 5A illustrates a reaction of tin-containing precursors 101-2A and a co-reagent 103 to form a tin-based photoresist 102-2A according to some embodiments of the present disclosure. A tin-containing precursor 101-2A may include a chelating alkyl-amide ligand featuring a tin-based heterocycle bound κ²-C, N with an alkyl R′ group on the ligand backbone, as described above with reference to FIG. 3. A co-reagent 103 may include water, carboxylic acid, phosphonic acid, sulphonic acid, or hydrogen peroxide, as described above with reference to FIG. 1. The tin-containing precursor 101-2A and the co-reagent 103 may be deposited on a substrate 100 using a deposition process (e.g., CVD) to form a tin-based photoresist 102-2A having tin clusters with a football-shaped structure 109. The tin-based photoresist 102-2A may further include R\hat{ } groups. The R\hat{ } groups may include CH₂(CHR′)(CH₂)ₙNMeH.

FIG. 5B illustrates a reaction of tin-containing precursors 101-2B and a co-reagent 103 to form a tin-based photoresist 102-2B according to some embodiments of the present disclosure. A tin-containing precursor 101-2B may include a chelating alkyl-amine ligand featuring a 5-membered or 6-membered tin-based heterocycle bound κ²-C, N with an alkyl R′ group on the ligand backbone, as described above with reference to FIG. 3. A co-reagent 103 may include water, carboxylic acid, phosphonic acid, sulphonic acid, or hydrogen peroxide, as described above with reference to FIG. 1. The tin-containing precursor 101-2B and the co-reagent 103 may be deposited on a substrate 100 using a deposition process (e.g., CVD) to form a tin-based photoresist 102-2B having tin clusters with a football-shaped structure 109. The tin-based photoresist 102-2B may further include R\hat{ } groups. The R\hat{ } groups may include CH₂(CHR′)(CH₂)ₙNMe₂.

FIG. 6 illustrates example reactions of a tin-based photoresist according to some embodiments of the present disclosure. After exposing a substrate 100 to a tin-containing precursor 101 and a co-reagent 103, a tin-based photoresist 102 may be deposited on the substrate 100 (e.g., as shown in FIG. 1B). The tin-based photoresist 102 may include tin clusters with a drum-shaped structure 108 or a football-shaped structure 109. The tin-based photoresist 102 may be selectively exposed to EUV 115 (e.g., using a mask 117), as shown in FIG. 1C, to form activated regions 104 of the tin-based photoresist 102. In some embodiments, the activated regions 104 may include activated and/or small scale crosslinking of tin clusters with a drum-shaped structure 108 or a football-shaped structure 109 by a crosslinking bond 110 (e.g., as shown as X in FIG. 6) including, for example, a carbonate bond, a hydroxyl bond, an oxygen bond, or an R—R group bond, the R—R group bond including any suitable R group including one or more of R* (i.e., R¹), R″ (i.e., R²), R′, R⁰, and R\hat{ }, as described above in FIGS. 2-5. The tin-based photoresist 102 may be exposed to heat 119 (e.g., baked), as shown in FIG. 1D, to form crosslinked regions 106 of the tin-based photoresist 102. The crosslinked regions 106 may include large scale crosslinking of tin clusters with a drum-shaped structure 108 or a football-shaped structure 109 by crosslinking bonds 110. The non-crosslinked R groups shown in FIG. 6 may include any suitable R groups (e.g., R*, R″, R′, R⁰, R\hat{ }), as described above in FIGS. 2-5.

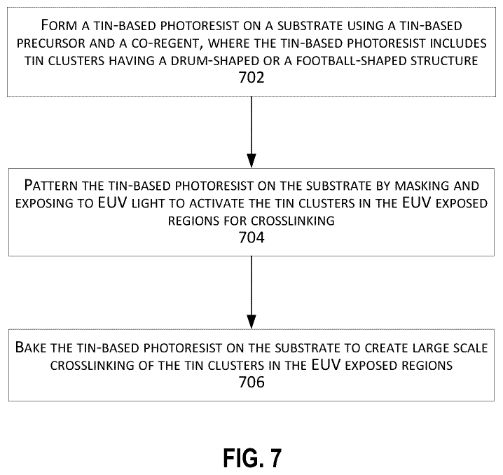

FIG. 7 is a schematic flow diagram listing example operations that may be associated with forming a tin-based photoresist according to some embodiments of the present disclosure. At 702, a thin-based photoresist 102 may formed on a substrate 100 using a deposition process, such as CVD, by exposing the substrate 100 to a tin-containing precursor 101 and a co-reagent 103. The tin-based photoresist 102 may include tin clusters having a drum-shaped structure 108 or a football-shaped structure 109. At 704, the tin-based photoresist 102 may be selectively exposed to EUV 115 to form activated regions 104 in the tin-based photoresist 102. At 706, the tin-based photoresist 102 may be exposed to heat 119 to form regions 106 of large scale crosslinked tin clusters in the tin-based photoresist 102.

The following paragraphs provide various examples of the embodiments disclosed herein.

Example 1 is a method for forming a tin-based photoresist, including forming a photoresist on a substrate by exposing a precursor and a co-reagent to the substrate, wherein the precursor has a formula R¹R²Sn(N(CH₃)₂)₂, and R¹ and R² are selected from the group consisting of neo-silyl, neo-pentyl, phenyl, benzyl, methyl-bis(trimethylsilyl), methyl, ethyl, isopropyl, tert-butyl, n-butyl, N,N-dimethylpropylamine, and N,N-dimethlybutylamine; the co-reagent includes water, carboxylic acid, phosphonic acid, sulphonic acid, or hydrogen peroxide; and the photoresist includes tin clusters; selectively exposing the photoresist to extreme ultraviolet radiation (EUV); and exposing the photoresist to heat to form crosslinking between the tin clusters in an EUV exposed region.

Example 2 may include the subject matter of Example 1, and may further specify that R¹ and R² are alkyl groups and the precursor is a dialkyl tin bisamide.

Example 3 may include the subject matter of Examples 1 or 2, and may further specify that selectively exposing the photoresist to EUV includes using a mask to create exposed and unexposed regions of the photoresist.

Example 4 may include the subject matter of any of Examples 1-3, and may further specify that exposing the photoresist to heat includes baking the photoresist at a temperature between 70 degrees Celsius and 250 degrees Celsius.

Example 5 may include the subject matter of any of Examples 1-4, and may further specify that the tin clusters in the photoresist have a drum-shaped structure.

Example 6 may include the subject matter of any of Examples 1-5, and may further specify that the tin clusters are crosslinked by a carbonate bond, a hydroxyl bond, an oxygen bond, or an R—R group bond, the R group including one or more of R¹ and R².

Example 7 may include the subject matter of Example 3, and may further include developing the photoresist; and removing the unexposed regions of the photoresist.

Example 8 may include the subject matter of any of Examples 1-7, and may further specify that forming the photoresist includes a chemical vapor deposition (CVD) processor or an atomic layer deposition (ALD) process.

Example 9 may include the subject matter of any of Examples 1-8, and may further specify that a thickness of the photoresist is between 10 nanometers and 100 nanometers.

Example 10 is a method for forming a tin-based photoresist, including forming a photoresist on a substrate by exposing a precursor and a co-reagent to the substrate, wherein the precursor includes a chelating alkyl-amide ligand, or a chelating alkyl-amine ligand, featuring a 5 or 6 membered tin-based heterocycle bound κ²-C,N with an alkyl group on the ligand backbone; the co-reagent includes water, carboxylic acid, phosphonic acid, sulphonic acid, or hydrogen peroxide, and the photoresist includes tin clusters; selectively exposing the photoresist to extreme ultraviolet radiation (EUV); and exposing the photoresist to heat to form crosslinking between the tin clusters in an EUV exposed region.

Example 11 may include the subject matter of Example 10, and may further specify that the alkyl group includes methyl, ethyl, vinyl, hydrogen, or tert-butyl.

Example 12 may include the subject matter of Examples 10 or 11, and may further specify that the tin clusters in the photoresist have a football-shaped structure.

Example 13 may include the subject matter of any of Examples 10-12, and may further specify that the tin clusters are crosslinked by a carbonate bond, a hydroxyl bond, an oxygen bond, or an R—R group bond, the R group including one or more of an alkyl group, an aryl group, CH₂(CHR′)(CH₂)ₙNMeH, and CH₂(CHR′)(CH₂)ₙNMe₂.

Example 14 may include the subject matter of any of Examples 10-13, and may further specify that selectively exposing the photoresist to EUV includes using a mask to create exposed and unexposed regions of the photoresist, and the method may further include developing the photoresist; and removing the unexposed regions of the photoresist.

Example 15 may include the subject matter of any of Examples 10-14, and may further specify that forming the photoresist includes a chemical vapor deposition (CVD) process or an atomic layer deposition (ALD) process.

Example 16 is an apparatus, including a substrate; and a photoresist on the substrate, wherein the photoresist includes tin clusters having a drum-shaped structure or a football-shaped structure, and wherein a region of the photoresist includes crosslinked tin clusters.

Example 17 may include the subject matter of Example 16, and may further specify that the tin clusters are crosslinked by a carbonate bond, a hydroxyl bond, an oxygen bond, or an R—R group bond, the R group including one or more of neo-silyl, neo-pentyl, phenyl, benzyl, methyl-bis(trimethylsilyl), methyl, ethyl, isopropyl, vinyl, tert-butyl, n-butyl, N,N-dimethylpropylamine, N,N-dimethlybutylamine, CH₂(CHR′)(CH₂)ₙNMeH, and CH₂(CHR′)(CH₂)ₙNMe₂.

Example 18 may include the subject matter of Examples 16 or 17, and may further specify that a thickness of the photoresist is between 10 nanometers and 100 nanometers.

Example 19 may include the subject matter of any of Examples 16-18, and may further specify that the substrate includes a semiconductor material.

Example 20 may include the subject matter of any of Examples 16-19, and may further specify that the photoresist is a negative-type photoresist.

1. A method for forming a tin-based photoresist, comprising:
forming a photoresist on a substrate by exposing a precursor and a co-reagent to the substrate, wherein:
the precursor has a formula R¹R²Sn(N(CH₃)₂)₂, and R¹ and R² are selected from the group consisting of neo-silyl, neo-pentyl, phenyl, benzyl, methyl-bis(trimethylsilyl), methyl, ethyl, isopropyl, tert-butyl, n-butyl, N,N-dimethylpropylamine, and N,N-dimethlybutylamine;
the co-reagent includes water, carboxylic acid, phosphonic acid, sulphonic acid, or hydrogen peroxide; and
the photoresist includes tin clusters;
selectively exposing the photoresist to extreme ultraviolet radiation (EUV); and
exposing the photoresist to heat to form crosslinking between the tin clusters in an EUV exposed region.

2. The method of claim 1, wherein R¹ and R² are alkyl groups and the precursor is a dialkyl tin bisamide.

3. The method of claim 1, wherein selectively exposing the photoresist to EUV includes using a mask to create exposed and unexposed regions of the photoresist.

4. The method of claim 1, wherein exposing the photoresist to heat includes baking the photoresist at a temperature between 70 degrees Celsius and 250 degrees Celsius.

5. The method of claim 1, wherein the tin clusters in the photoresist have a drum-shaped structure.

6. The method of claim 1, wherein the tin clusters are crosslinked by a carbonate bond, a hydroxyl bond, an oxygen bond, or an R—R group bond, the R group including one or more of R¹ and R².

7. The method of claim 3, further comprising:
developing the photoresist; and
removing the unexposed regions of the photoresist.

8. The method of claim 1, wherein forming the photoresist includes a chemical vapor deposition (CVD) processor or an atomic layer deposition (ALD) process.

9. The method of claim 1, wherein a thickness of the photoresist is between 10 nanometers and 100 nanometers.

10. A method for forming a tin-based photoresist, comprising:
forming a photoresist on a substrate by exposing a precursor and a co-reagent to the substrate, wherein:
the precursor includes a chelating alkyl-amide ligand, or a chelating alkyl-amine ligand, featuring a 5 or 6 membered tin-based heterocycle bound κ²-C, N with an alkyl group on the ligand backbone;
the co-reagent includes water, carboxylic acid, phosphonic acid, sulphonic acid, or hydrogen peroxide, and
the photoresist includes tin clusters;
selectively exposing the photoresist to extreme ultraviolet radiation (EUV); and
exposing the photoresist to heat to form crosslinking between the tin clusters in an EUV exposed region.

11. The method of claim 10, wherein the alkyl group includes methyl, ethyl, vinyl, hydrogen, or tert-butyl.

12. The method of claim 10, wherein the tin clusters in the photoresist have a football-shaped structure.

13. The method of claim 10, wherein the tin clusters are crosslinked by a carbonate bond, a hydroxyl bond, an oxygen bond, or an R—R group bond, the R group including one or more of an alkyl group, an aryl group, CH₂(CHR′)(CH₂)ₙNMeH, and CH₂(CHR′)(CH₂)ₙNMe₂.

14. The method of claim 10, wherein selectively exposing the photoresist to EUV includes using a mask to create exposed and unexposed regions of the photoresist, and the method further comprising:
developing the photoresist; and
removing the unexposed regions of the photoresist.

15. The method of claim 10, wherein forming the photoresist includes a chemical vapor deposition (CVD) process or an atomic layer deposition (ALD) process.

16. An apparatus, comprising:
a substrate; and
a photoresist on the substrate, wherein the photoresist includes tin clusters having a drum-shaped structure or a football-shaped structure, and wherein a region of the photoresist includes crosslinked tin clusters.

17. The apparatus of claim 16, wherein the tin clusters are crosslinked by a carbonate bond, a hydroxyl bond, an oxygen bond, or an R—R group bond, the R group including one or more of neo-silyl, neo-pentyl, phenyl, benzyl, methyl-bis(trimethylsilyl), methyl, ethyl, isopropyl, vinyl, tert-butyl, n-butyl, N,N-dimethylpropylamine, N,N-dimethlybutylamine, CH₂(CHR′)(CH₂)ₙNMeH, and CH₂(CHR′)(CH₂)ₙNMe₂.

18. The apparatus of claim 16, wherein a thickness of the photoresist is between 10 nanometers and 100 nanometers.

19. The apparatus of claim 16, wherein the substrate includes a semiconductor material.

20. The apparatus of claim 16, wherein the photoresist is a negative-type photoresist.
